(19) United States
(12) Patent Application Publication
(10) Pub. No.: US 2026/0239765 A1
(43) Pub. Date: Aug. 13, 2026

(54) IMAGE SENSING DEVICE

(71) Applicant: SK hynix Inc., Icheon-si (KR)

(72) Inventor: Young Gyu YOU, Icheon-si (KR)

(21) Appl. No.: 19/228,174

(22) Filed: Jun. 4, 2025

(30) Foreign Application Priority Data
Feb. 11, 2025 (KR) 10-2025-0017183

(51) Int. Cl. H10F 39/00; H04N 25/709; H10F 39/18

(52) U.S. Cl. CPC H10F 39/807; H04N 25/709; H10F 39/182

(57) ABSTRACT

An image sensing device is provided to comprise: a first photodetector disposed in a first pixel area; a second photodetector disposed in a second pixel area disposed on one side of the first pixel area, each of the first photodetector and the second photodetector configured to produce electrical signals in response to incident light; a charge flooding barrier disposed in a non-pixel area located between the first pixel area and the second pixel area, the non-pixel area disposed without including any photodetector for detecting the incident light; and a charge flooding barrier control node overlapping the charge flooding barrier and configured to control a potential of the charge flooding barrier.

This application claims priority to and the benefit of Korean Patent Application No. 10-2025-0017183, filed on Feb. 11, 2025, the disclosure of which is incorporated herein by reference in its entirety.

### TECHNICAL FIELD

Embodiments of the present disclosure relate to an image sensing device.

### BACKGROUND

With the development of the information and communication industry and the digitalization of electronic devices, image sensors with improved performance are being used in various fields such as digital cameras, camcorders, mobile phones, PCS (personal communication systems), game devices, security cameras, and medical micro cameras. In general, an image sensor has a pixel area including a photodiode and a peripheral circuit area. A unit pixel includes a photodiode and a transistor. The transistor is placed between the photodiode and a floating diffusion area to transfer charges generated by the photodiode to the floating diffusion area.

### SUMMARY

Some implementations of the disclosed technology provide an image sensing device that may control the potential of a charge flooding barrier.

In one aspect, an image sensing device may include a first photodetector disposed in a first pixel area; a second photodetector disposed in a second pixel area disposed on one side of the first pixel area, each of the first photodetector and the second photodetector configured to produce electrical signals in response to incident light; a charge flooding barrier disposed in a non-pixel area located between the first pixel area and the second pixel area, the non-pixel area disposed without including any photodetector for detecting the incident light; and a charge flooding barrier control node overlapping the charge flooding barrier and configured to control a potential of the charge flooding barrier.

According to various embodiments, an image sensing device is provided to include a first photodetector and a second photodetector that are configured to generate photocharges corresponding to an intensity of incident light; a first transfer transistor connected between the first photodetector and a floating diffusion area and configured to transfer photocharges accumulated in the first photodetector to the floating diffusion area; a second transfer transistor connected to the second photodetector and the floating diffusion area and configured to transfer photocharges accumulated in the second photodetector to the floating diffusion area; and a charge flooding barrier control node disposed between the first transfer transistor and the floating diffusion area and between the second transfer transistor and the floating diffusion area, the charge flooding barrier control node configured to control a potential of a charge flooding barrier disposed between the first photodetector and the second photodetector.

In the image sensing device according to the embodiment of the present disclosure, electrodes of the first transmission transistor and the charge flooding barrier control node may be provided between one electrode of the second transmission transistor and the floating diffusion area, and the negative bias voltage may be applied to the charge flooding barrier control node, thereby variably controlling the potential of the charge flooding barrier. Accordingly, the length of the auto-focusing possible section can be increased even at high illuminance.

Various implementations of the disclosed technology will be described in the detailed description. However, it should be understood that the detailed description are given by illustration only, since variations and improvements of the disclosed embodiments and other embodiments may be made based on what is described or illustrated in this document.

### DETAILED DESCRIPTION

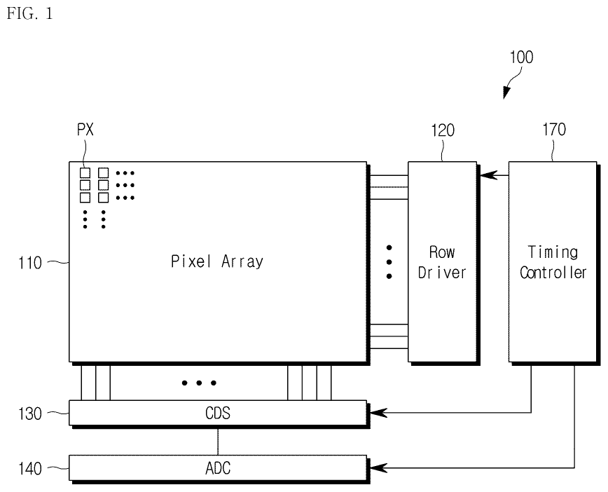

FIG. 1 is an example of a block view showing an image sensing device based on some implementations of the disclosed technology.

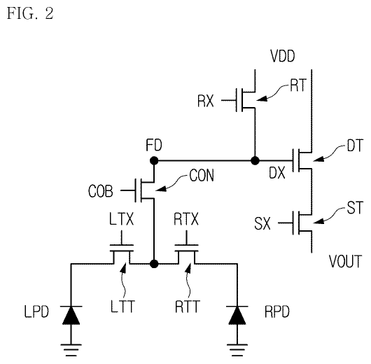

FIG. 2 is an example of a circuit view of a pixel array shown in FIG. 1 based on some implementations of the disclosed technology.

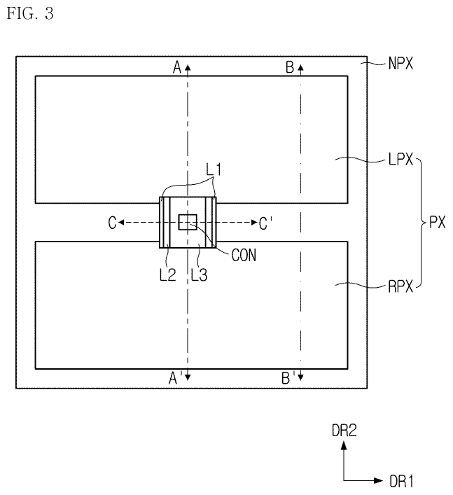

FIG. 3 is an example of a plane view of a pixel based on some implementations of the disclosed technology.

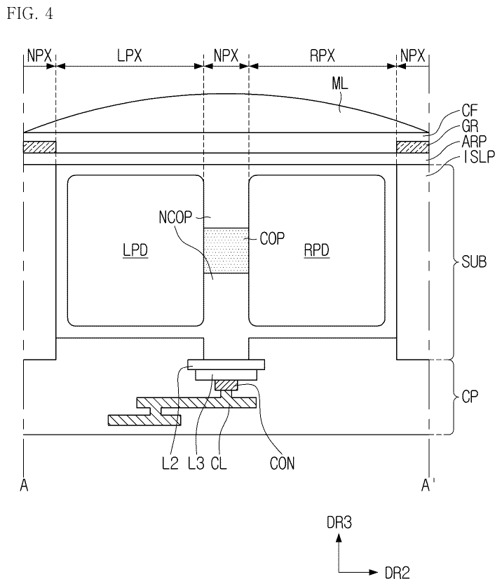

FIG. 4 is a cross-sectional view cut along A-A′ of FIG. 3.

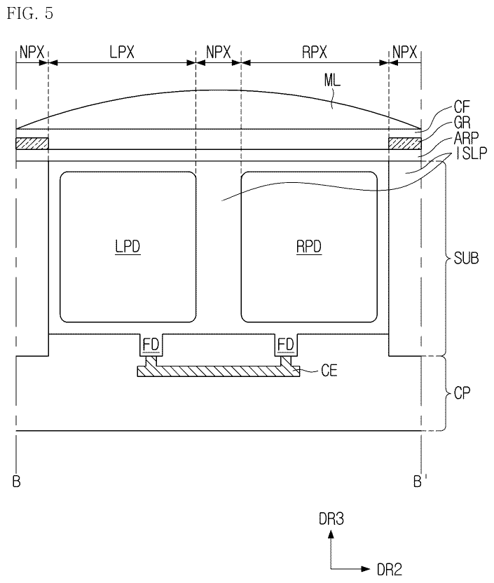

FIG. 5 is a cross-sectional view cut along B-B′ of FIG. 3.

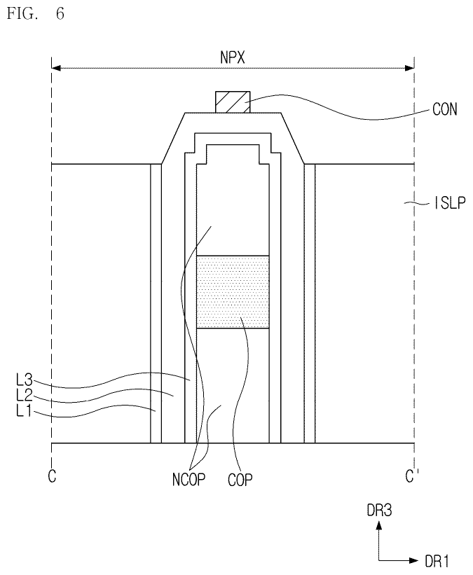

FIG. 6 is a cross-sectional view cut along C-C′ of FIG. 3.

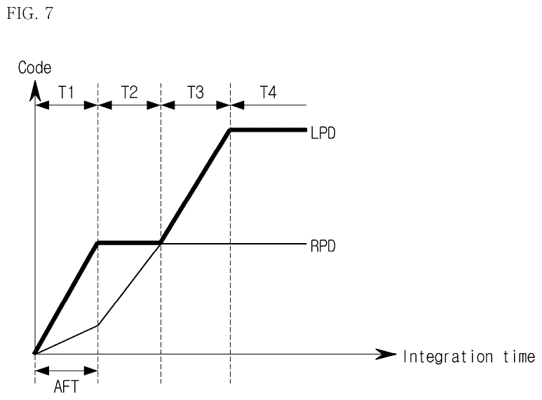

FIG. 7 is an example of a graph showing a code of a first detector and a second detector according to a light irradiation time (integration time) based on some implementations of the disclosed technology.

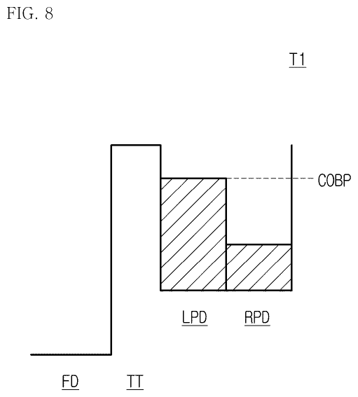

FIG. 8 is an example of a view showing potentials of a floating diffusion area, a transfer transistor, a first photodetector, and a second photodetector in a first period (T1) based on some implementations of the disclosed technology.

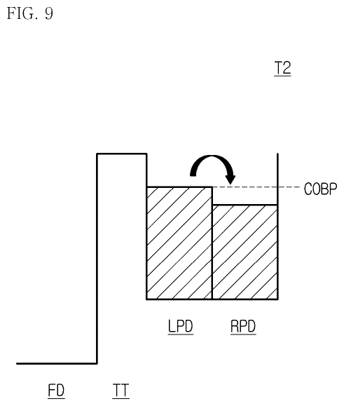

FIG. 9 is an example of a view showing potentials of a floating diffusion area, a transfer transistor, a first photodetector, and a second photodetector in a second period (T2) based on some implementations of the disclosed technology.

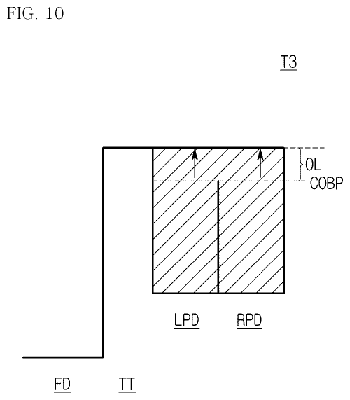

FIG. 10 is an example of a diagram showing potentials of a floating diffusion area, a transfer transistor, a first photodetector, and a second photodetector in a third period (T3) based on some implementations of the disclosed technology.

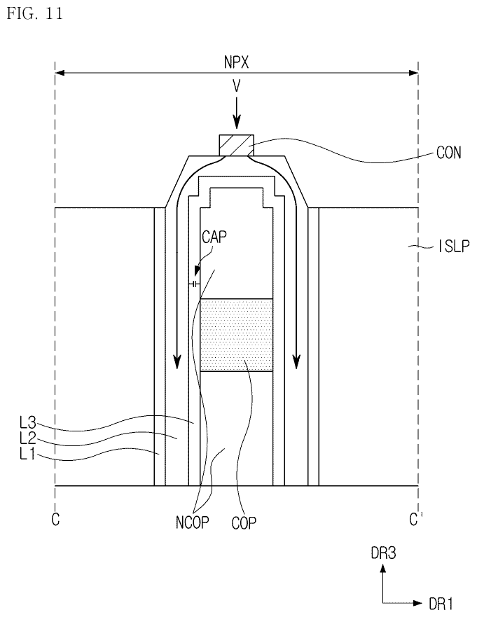

FIG. 11 is an example of a schematic diagram showing a voltage being applied to a charge flooding barrier control unit based on some implementations of the disclosed technology.

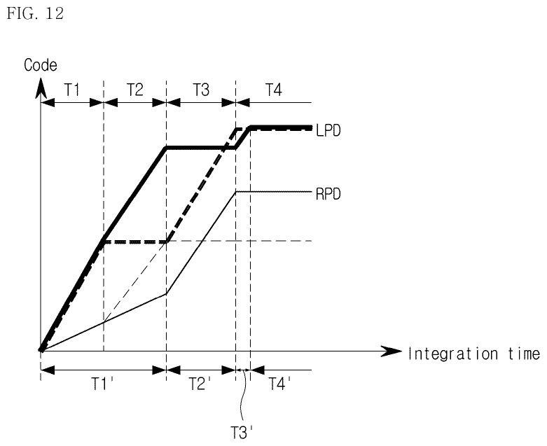

FIG. 12 is a graph showing a code of a first detector and a second detector according to the light irradiation time (integration time) of an image sensing device based on some implementations of the disclosed technology.

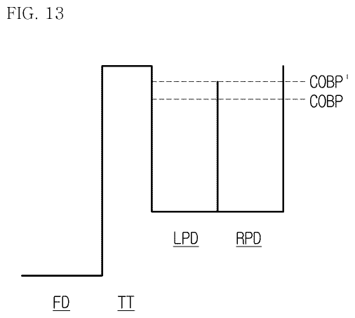

FIG. 13 is a diagram showing the potential of a charge flooding barrier based on some implementations of the disclosed technology.

### DETAILED DESCRIPTION

Description will now be given in detail according to exemplary embodiments disclosed herein, with reference to the accompanying drawings.

For the sake of brief description with reference to the drawings, the same or equivalent components may be provided with the same reference numbers, and description thereof will not be repeated. “And/or” includes any combination of one or more of the associated configurations that can be defined.

The terms “below,” “lower,” “above,” and “upper” are used to describe the relationships between components depicted in the drawings.

Terms such as “comprise” or “comprising” are used herein and should be understood that they are intended to indicate an existence of several components, functions or steps, disclosed in the specification, and it is also understood that greater or fewer components, functions, or steps may likewise be utilized. However, the present disclosure may be embodied in various modified examples, and is not limited to embodiments described herein.

FIG. 1 is a block view showing an image sensing device according to one embodiment.

Referring to FIG. 1, the image sensing device 100 may include a pixel array 110, a row driver 120, a correlated double sampler CDS 130, an analog-digital converter ADC 140, an output buffer 150, a column driver 160, and a timing controller 170.

The pixel array 110 may include a plurality of pixels (PX). The pixels (PX) may be arranged in a matrix manner along the row direction and the column direction, but the embodiments are not limited thereto. The pixels (PX) may include red pixels, green pixels, and blue pixels, but the embodiments are not limited thereto, and may further include white pixels or infrared pixels.

The plurality of pixels (PX) may be electrically connected to the row driver 120. The plurality of pixels (PX) may be respectively connected to control lines extended from the row driver 120. The control lines may be transmission lines or boosting control lines as illustrated in FIG. 1, but the embodiments are not limited thereto. In some implementations, the row driver 120 may be configured to activate the pixel array to perform a specific operation for pixels included in the corresponding low based on commands and control signals supplied by the timing controller 170.

The correlate double sampler 130 may be configured to perform a sequential sampling and holding for a reference signal and an image signal which are provided to each of the column lines from the pixel array 110. Thus, the correlate double sampler 130 may sample and hold the levels of the reference and image signal corresponding to each of the columns of the pixel array 110.

Based on the control signal from the timing controller 180, the correlate double sampler 130 may transmit the reference signal and image signal of each column to the ADC 140 as the correlate double sampling signal.

The ADC 140 may convert the correlate double sampling signal for each column output from the correlate double sampler 130 into a digital signal, and then output image data. In one embodiment, the ADC 140 may convert the correlate double sampling signal generated by the correlate double sampler 130 for each column into a digital signal and output the converted digital signal.

The ADC 140 may include a plurality of column counters corresponding to the columns of the pixel array 110, respectively. Each column of the pixel array 110 may be connected to each column counter, and image data may be generated by converting the correlate double sampling signal corresponding to each column into a digital signal, using the column counters. The timing controller 170, the correlate double sampler 130, and the ADC 140 illustrated in FIG. 1 may further perform operations as known in the art

FIG. 2 is an equivalent circuit of a pixel array shown in FIG. 1 based on some implementations of the disclosed technology.

Referring to FIG. 2, the circuit diagram of the pixel may correspond to an equivalent circuit of each pixel (PX) included in the pixel array (see 110 of FIG. 1).

A pixel (PX) may include a photodetector (LPD, RPD), a transfer transistor (LTT, RTT), a reset transistor (RT), a floating diffusion area (FD), a driver transistor (DT), and a select transistor (ST).

The photodetector (LPD, RPD) can generate and accumulate photocharges corresponding to the intensity of incident light. For example, the photodetector (LPD, RPD) can be implemented as a photodiode, a phototransistor, a photogate, a pinned photodiode, or a combination thereof. When the photodetector (LPD, RPD) is implemented as a photodiode, it can be an area doped with an impurity of a second conductivity type (e.g., N-type) in a substrate having a first conductivity type (e.g., P-type). The photodetector (LPD, RPD) can be a photodetector for phase detection.

Each transistor (LTT, RTT, RT, DT, and ST) may have a first electrode (or one electrode, or the other electrode) and a second electrode (or the other electrode, or one electrode), and hereinafter, the first electrode and the second electrode may be referred to as a source electrode or a drain electrode, respectively.

Each of the transfer transistor (LTT, RTT) may be connected between the photodetector (LPD, RPD) and the floating diffusion area (FD). The transfer transistor LTT may be connected between the photodetector LPD and the floating diffusion area (FD) and the transfer transistor RTT may be connected between the photodetector RPD and the floating diffusion area (FD). The first transfer transistor (LTT) may be turned on or off in response to a first transfer control signal (LTX) applied to a gate electrode, and the turned-on first transfer transistor (LTT) may transfer photocharges accumulated in the first photodetector (LPD) to the floating diffusion area (FD). A source electrode of the first transfer transistor (LTT) may be connected to the first photodetector (LPD), and a drain electrode may be connected to the floating diffusion area (FD).

The second transfer transistor (RTT) may be turned on or off in response to a second transfer control signal (RTX) applied to the gate electrode, and the turned-on second transfer transistor (RTT) can transfer the photocharge accumulated in the second photodetector (RPD) to the floating diffusion area (FD). The source electrode of the second transfer transistor (RTT) may be connected to the second photodetector (RPD), and the drain electrode can be connected to the floating diffusion area (FD).

A charge flooding barrier control node (CON) may be placed between each of the transfer transistor (LTT, RTT) and the floating diffusion area (FD). The charge flooding barrier control node (CON) may be placed between the transfer transistor LTT and the floating diffusion area (FD) and between the transfer transistor RTT and the floating diffusion area (FD). A control voltage (COB) may be applied to the charge flooding barrier control node (CON). The control voltage (COB) may be a negative bias voltage, but the embodiments are not limited thereto.

The reset transistor (RT) is connected between the power supply voltage (VDD) and the floating diffusion area (FD), and may reset the voltage of the floating diffusion area (FD) to the power supply voltage (VDD) in response to a reset control signal (RX) applied to the gate electrode. The power supply voltage (VDD) may be applied to the source electrode of the reset transistor (RT), and the drain electrode may be connected to the floating diffusion area (FD).

The floating diffusion area (FD) may accumulate photocharges that are originally generated or accumulated in first and second photodetectors (LPD, RPD), respectively, and are subsequently transferred from the first and second photodetectors (LPD, RPD) by the transfer transistors (LTT, RTT), respectively. For example, the floating diffusion area (FD) may be an area doped with an impurity of a second conductivity type (e.g., N type) in a substrate having a first conductivity type (e.g., P type), and the substrate and the impurity doped area may be modeled as a junction capacitor. The floating diffusion area (FD) may be connected to a gate electrode of the driver transistor (DT), a drain electrode of the transfer transistor (LTT, RTT), and a drain electrode of the reset transistor (RT). A floating diffusion electrode may be arranged in the floating diffusion area (FD).

The driver transistor (DT) is connected between the power supply voltage (VDD) and the selection transistor (ST), and may amplify the change in the electric potential of the floating diffusion area (FD) that receives the photocharges accumulated in the photodetector (LPD, RPD) and transmit it to the selection transistor (ST). The gate electrode of the driver transistor (DT) may be connected to the floating diffusion area (FD), the power supply voltage (VDD) may be applied to the source electrode, and the drain electrode may be connected to the source electrode of the selection transistor (ST).

The selection transistor (ST) is turned on by a selection control signal (SX) applied to the gate electrode and may output an electrical signal transmitted from the driver transistor (DT) as an output signal (VOUT) to the output signal line.

The voltage of the floating diffusion area (FD) may be determined by the amount of photocharge transmitted through the transfer transistor (LTT, RTT), and the voltage of the floating diffusion area (FD) may be an indicator of the amount of photocharge in the floating diffusion area (FD), e.g., the voltage at the FD may be lowered as the amount of photocharge increases in some implementations.

FIG. 3 is a plan view of a pixel according to one embodiment.

Referring to FIG. 3, a pixel according to one embodiment includes a pixel area (PX), and the pixel area (PX) may include a first pixel area (PX1) and a second pixel area (RPX) adjacent to the first pixel area (LPX). The first pixel area (LPX) may be a first phase detection pixel area, and the second pixel area (RPX) may be a second phase detection pixel area, but the embodiments are not limited thereto. A pixel further includes a non-pixel area (NPX), and the non-pixel area (NPX) surrounds the pixel area (PX1, PX2) and may also be arranged between adjacent pixel areas (PX1, PX2). In the example as shown in FIG. 3, the first pixel area (LPX) and the second pixel area (RPX) may be separated from each other by the non-pixel area (NPX). The non-pixel region (NPX) is a region without a photodetector and thus does not detect incident light.

Although only one pixel is illustrated in FIG. 3, the embodiments are not limited thereto, and adjacent pixels may share a floating diffusion area (see FD in FIG. 2). For example, pixels arranged in a 2×2 matrix including two rows and two columns may share a floating diffusion area (FD), or pixels arranged in a 3×3 matrix including three rows and three columns may share a floating diffusion area (FD). In some implementations, pixels arranged in a matrix other than the 2×2 matrix and 3×3 matrix can share a floating diffusion area (FD).

A charge flooding barrier control unit (CON), which will be discussed in more detail later in this patent document, may be arranged between the first pixel area (LPX) and the second pixel area (RPX). The charge flooding barrier control unit (CON) may be arranged in the non-pixel area (NPX) outside of the pixel area (PX) at a location in the NPX between the first detector (LPD) and the second detector (RPD).

In some implementations, the image sensing device according to one embodiment may further include a plurality of layers (L1, L2, and L3). The third layer (L3) may cover or disposed over the charge flooding barrier control unit (CON), and the second layer (L2) may cover or disposed over the third layer (L3) and the charge flooding barrier control unit (CON). The first layer (L1) may be arranged on a side of the second layer (L2). Although a plurality of layers (L1, L2, and L3) are illustrated in FIG. 3, the arrangement or number of the plurality of layers (L1, L2, and L3) in FIG. 3 may be changed as needed.

The charge flooding barrier control unit (CON) and multiple layers (L1, L2, and L3) will be described in detail later.

FIG. 4 is a cross-sectional view cut along A-A′ passing through the charge flooding barrier control unit (CON) of FIG. 3.

Referring to FIGS. 3 and 4, the image sensing device according to one embodiment may include a circuit portion (CP), a substrate portion (SUB) on the circuit portion (CP), an anti-reflection layer (ARP) on the substrate portion (SUB), a grid portion (GR) on the anti-reflection layer (ARP), a color filter (CF) on the grid portion (GR), and a micro lens (ML) on the color filter (CF).

The circuit portion (CP) is arranged on the lower surface of the substrate portion (SUB) and may include transistors, a wiring layer, and an interlayer insulating layer. As illustrated in FIG. 4, the circuit portion (CP) may have a control line (CL) electrically connected to the charge flooding barrier control unit (CON). A negative bias voltage may be applied to the control line (CL), and the negative bias voltage applied to the control line (CL) may be provided to the charge flooding barrier control unit (CON). The charge flooding barrier control unit (CON) may be included in the circuit unit (CP). The interlayer insulating layer of the circuit unit (CP) may protrude upward (one side of DR3) in the pixel area (LPX, RPX), and conversely, may be recessed downward (the other side of DR3) in the non-pixel area (NPX).

The substrate portion (SUB) may include a charge flooding barrier (COP) positioned between the first photodetector (LPD) and the second photodetector (RPD) and a non-charge flooding barrier (NCOP) positioned above or below the charge flooding barrier (COP). When a pixel area (PX) receives an ample amount of light that each of the first and second photodetectors (LPX, RPX) accumulates more electrical charge than teach photodetector LPX or RPX can hold, this excess charge from each photodetector LPX or RPX can then overflow and spread into neighboring pixel areas, causing incorrect signaling in neighboring pixel areas and thus leading to smearing of images detected in adjacent pixel areas. The charge flooding barrier (COP) may correspond to a region with a specific electrical potential designed to divert the excess charge away by providing a controlled path for the excess charge to be removed from a pixel area (LPX, RPX) before it can flood into adjacent pixels. A potential of the charge flooding barrier (COP) may be higher than a potential of the non-charge flooding barrier (NCOP), and a potential of the charge flooding barrier (COP) may be lower than a potential of each photodetector (LPD, RPD). The photodetectors (LPD, RPD), the charge flooding barrier (COP), and the non-charge flooding barrier (NCOP) may be formed to have different potentials from one another depending on the ion implantation concentrations.

In the non-pixel area (NPX), a third layer (L3) may be arranged between the charge flooding barrier control unit (CON) and the non-charge flooding barrier (NCOP). The third layer (L3) and the charge flooding barrier control unit (CON) may be in direct contact. The second layer (L2) and the non-charge flooding barrier control unit (NCON) may be separated from each other with the third layer (L3) disposed between the second layer (L2) and the non-charge flooding barrier control unit (NCON). The second layer (L2) may have an upper surface to be in direct contact with the non-charge flooding barrier (NCOP) and may have a lower surface to be in direct contact with the third layer (L3). In the implementations, the charge flooding barrier control unit (CON) is disposed to overlap the charge flooding barrier COP.

The substrate portion (SUB) may be recessed in the non-pixel area (NPX) other than the non-pixel area (NPX) between photodetectors (LPD and RPD), and a separator (ISLP) may be arranged in the recessed area. The separator (ISLP) may include an insulating material and/or a conductive material. For example, examples of the insulating material may include hafnium oxide (HfOx), silicon oxide (SiOx), or tantalum oxide (TaOx), but the embodiments are not limited thereto. Examples of the conductive material may include polysilicon, but the embodiments are not limited thereto. For example, the separator (ISLP) may have a structure in which a conductive material is sandwiched between insulating materials, but the embodiments are not limited thereto.

An anti-reflection layer (ARP) may be disposed on the upper surface of the substrate portion (SUB). The anti-reflection layer (ARP) may include at least one insulating material, and may include, for example, hafnium oxide (HfOx), silicon oxide (SiOx), or tantalum oxide (TaOx), but the embodiments are not limited thereto. The anti-reflection layer (ARP) may serve to direct light passing through the color filter (CF) to the substrate portion (SUB) without reflecting the light.

In a non-pixel area (NPX) other than the non-pixel area (NPX) between each photodetector (LPD, RPD), a grid portion (GR) may be arranged on an upper surface of an anti-reflection layer (ARP). The grid portion (GR) may absorb or reflect light incident on the grid portion (GR). The grid portion (GR) may prevent light mixing between adjacent pixel areas. The grid portion (GR) may include a light absorbing material or a low-refractive-index layer. For example, when the grid portion (GR) includes a light absorbing material, it may include a metal material. The above metal material may include tungsten (W), but the embodiments are not limited thereto. For example, when the grid portion (GR) includes a low-refractive-index layer, the grid portion (GR) may include a low-refractive-index insulating material or an air structure. The metal material may include tungsten (W), but the embodiments are not limited thereto. For example, when the grid portion (GR) includes a low-refractive-index layer, the grid portion (GR) may include a low-refractive-index insulating material or an air structure.

A color filter (CF) may be arranged on the anti-reflection layer (ARP) and the grid portion (GR) on the upper surface of the substrate portion (SUB). The color filter (CF) may be configured to block a specific color from the light. The color filter (CF) may include a red color filter configured to block other colors than red light, a green color filter configured to block other colors than the green color, or a blue color filter configured to block other colors than the blue color. In some embodiments, the color filter (CF) may further include a white or black color filter.

A micro lens (ML) may be arranged on the color filter (CF). The micro lens (ML) may serve to receive light incident from the outside into the pixel area (LPX, RPX). In some implementations, the micro lens (ML) may have a shape of a convex lens that is convex upward, and may be formed of a material having a large difference in refractive index compared to the outside air (Air). For example, the refractive index of the micro lens (ML) may be about 1.5 to about 1.7, but is not limited thereto. As illustrated in FIG. 6, the micro lens (ML) is exemplified as being arranged without distinction between the first and second pixel areas (LPX, RPX) such that the micro lens (ML) is disposed to cover the first and second pixel areas (LPX, RPX), but is not limited thereto. For example, the micro lens (ML) may be arranged in each of the first and second pixel areas (LPX, RPX).

FIG. 5 is a cross-sectional view cut along B-B′ of FIG. 3.

Referring to FIGS. 3 and 5, the circuit portion (CP) may further include a connecting electrode (CE) connecting the floating diffusion area (FD) of each of the pixel areas (LPX, RPX). Although not illustrated in FIG. 5, the circuit portion (CP) may further include wiring or electrodes connected to the transistors (LTT, RTT, ST, DT, and RT) and the transistors (LTT, RTT, ST, DT, RT) described in FIG. 2. As illustrated in FIG. 5, a separator (ISLP) may be arranged in a non-pixel area (NPX) between the pixel areas (LPX, RPX) where a charge flooding barrier (COP) is not arranged as in FIG. 4. A detailed description of the material of the separator (ISLP) will be omitted as described above with reference to FIG. 4.

FIG. 6 is a cross-sectional view cut along C-C′ of FIG. 3. In FIG. 6, for convenience of explanation, the image sensing device is shown upside down, unlike in FIGS. 4 and 5 described above. In explaining FIG. 6, for convenience of explanation, one direction of the third direction (DR3) is referred to as the upper direction, but it may also be referred to as the lower direction, as in FIGS. 4 and 5.

Referring to FIG. 6, a non-charge flooding barrier (NCOP) may be disposed on the upper or lower side of the charge flooding barrier (COP). A third layer (L3) may be disposed on the side surface and the upper surface of the charge flooding barrier (COP) and the non-charge flooding barrier (NCOP). The third layer (L3) may surround the charge flooding barrier (COP) and the non-charge flooding barrier (NCOP). The third layer (L3) may be in direct contact with the side surface and the upper surface of the charge flooding barrier (COP) and the non-charge flooding barrier (NCOP). The third layer (L3) may include an insulating material.

A second layer (L2) may be arranged on the third layer (L3). The second layer (L2) may surround the third layer (L3), and may be in direct contact with the third layer (L3). The second layer (L2) may have electrical conductivity. For example, the second layer (L2) may include poly silicon, but the embodiments are not limited thereto. The second layer (L2) may cover the third layer (L3). The width of the second layer (L2) in the first direction (DR1) may be larger than the width of the third layer (L3) in the first direction (DR1). A predetermined voltage (or electric field) may be applied to the second layer (L2).

A first layer (L1) may be disposed between the second layer (L2) and the adjacent separator (ISLP). The first layer (L1) may be in direct contact with the second layer (L2) and the separator (ISLP). The first layer (L1) may include an insulating material. The first layer (L1) may include, for example, hafnium oxide (HfOx), silicon oxide (SiOx), or tantalum oxide (TaOx), but the embodiments are not limited thereto.

As described above, the separator (ISLP) may include a conductive material such as polysilicon. When the separator (ISLP) includes a conductive material, an electric field may be applied to the separator (ISLP). When an electric field is applied to the separator (ISLP), if the separator (ISLP) and the second layer (L2) are in direct contact, the electric field may also be transmitted to the second layer (L2). However, in the case of the image sensing device according to one embodiment, in order to apply an electric field by distinguishing the separator (ISLP) and the second layer (L2), a first layer (L1) including an insulating material may be placed between the second layer (L2) and the separator (ISLP).

A charge flooding barrier node (CON) may be arranged on the charge flooding barrier (COP). The charge flooding barrier node (CON) may be arranged directly on the upper surface of the second layer (L2). The charge flooding barrier node (CON) may be electrically connected to the control line (CL), as described above in FIG. 4. The charge flooding barrier node (CON) may include a conductive material, for example, a metal.

FIG. 7 is a graph showing codes of the first detector and the second detector according to the light irradiation time (integration time). In this present disclosure, the codes indicate the amount of light received at each detector (LPD, RPD) at the time of light irradiation. The dual correlation sampler (see 130 of FIG. 1) provides pixel signals corresponding to the amount of light received at each detector (LPD, RPD) to the ADC (see 140 of FIG. 1), and the ADC (140) converts the pixel signals of each detector (LPD, RPD), which are received from the dual correlation sampler 130, into digital values and these digital values are referred to as the codes.

FIG. 8 is a view showing the potentials of the floating diffusion area, the transfer transistor, the first photodetector, and the second photodetector in the first period (T1). FIG. 9 a view showing the potentials of the floating diffusion area, the transfer transistor, the first photodetector, and the second photodetector in the second period (T2). FIG. 10 is a diagram showing the potentials of the floating diffusion area, the transfer transistor, the first photodetector, and the second photodetector in the third period (T3). In FIG. 7, when light is irradiated, it is assumed that, during the same time, the amount of light applied to the first detector (LPD) is greater than the amount of light applied to the second detector (RPD). The potential of the first photodetector (LPD) and the potential of the second photodetector (RPD) may be greater than the potential of the transfer transistor (TT: meaning LTT, RTT in FIG. 2). The charge overflow barrier potential (COBP), which refers to the electrical potential energy level that acts as a threshold for accumulated charge within a pixel area, may be greater than the potential of the transfer transistor (TT: meaning LTT, RTT in FIG. 4) and less than the potential of the first photodetector (LPD).

Referring to FIG. 7 and FIG. 8, in the first period (T1), the variation over time in the photocharge amount may be greater in the first detector (LPD) than in the second detector (RPD). The auto-focusing function is operational in the first period (T1) and thus the first period (T1) may be referred to as an auto-focusing possible section. Specifically, in the first period (T1), the variation over time in the photocharge amount in the first detector (LPD) and the second detector (RPD) are different from each other (or there is a difference in sensitivity). Thus, in the first period (T1), the auto-focusing is operational through the code difference between the first detector (LPD) and the second detector (RPD). In the first period (T1), the first detector (LPD) may be photocharged up to the charge flooding barrier potential (COBP).

Referring to FIG. 7 and FIG. 9, in the second period (T2), the photocharges that exceed the charge overflow barrier potential (COBP) can move to the second detector (LPD). In the second period (T2), as in the first period (T1), since the amount of light applied to the first detector (LPD) is greater than the amount of light applied to the second detector (RPD) during the same time, the amount of photocharges accumulated in the second detector (RPD) over time can increase to reflect the amount of photocharges accumulated in the first detector (LPD) over time in the first period (T1). In the second period (T2), the auto-focusing function is not operational since there is no change in the code of the first detector (LPD), only the code of the second detector (RPD) increases, and the photocharges of the first detector (LPD) move to the second detector (RPD).

Referring to FIG. 7 and FIG. 10, in the third period (T3), since the second detector (RPD) is also charged with photocharges equal to the charge flooding barrier potential (COBP), photocharges may begin to be charged at the charge flood level (OL). Meanwhile, in the third period (T3), the photocharges of the first detector (LPD) may be read out, and not only the photocharges charged in the first detector (LPD) but also the photocharges at the charge flood level (OL) may be read out. Accordingly, in the third period (T3), the code of the first detector (LPD) may increase, while the code of the second detector (RPD) may not change. In the fourth period (T4), the code of the first detector (LPD) may not change.

As described above, auto-focusing is possible in the process of asymmetrically irradiating each detector (LPD, RPD), and specifically, auto-focusing may be possible until the photocharge is charged to the charge flooding barrier potential (COBP) in the first detector (LPD). In a low-light environment, auto-focusing is possible because there is time until the photocharge is charged to the charge flooding barrier potential (COBP) in the first detector (LPD), but in a high-light environment, auto-focusing may be difficult because the photocharge is charged to the charge flooding barrier potential (COBP) relatively quickly in the first detector (LPD).

However, according to an image sensing device according to one embodiment, auto-focusing may be possible even in a high-light environment by variably controlling the charge overflow barrier potential (COBP).

FIG. 11 is a schematic diagram showing the voltage being applied to a charge flooding barrier control unit according to one embodiment.

Referring to FIG. 11, a predetermined voltage (V) may be applied to the charge flooding barrier control unit (CON). Since the second layer (L2) includes a conductive material as described above, when the voltage (V) is applied to the charge flooding barrier control unit (CON), an electric field may be formed in the second layer (L2). The second layer (L2) may form a cap (CAP) with the charge flooding barrier (COP) and the third layer (L3) interposed therebetween. That is, the potential of the charge flooding barrier (COP) may be varied through the voltage (V) applied to the charge flooding barrier control unit (CON). The voltage (V) may be a negative bias voltage, but the embodiments are not limited thereto

FIG. 12 is a graph showing the code of the first detector and the second detector according to the light irradiation time (integration time) of the image sensing device according to one embodiment. FIG. 13 is a diagram showing the potential of a charge flooding barrier according to one embodiment.

Referring to FIGS. 12 and 13, the potential of the charge flooding barrier (COBP′) can be lowered compared to before through the negative bias voltage (V) described in FIG. 11.

Accordingly, since the amount of photoelectric charge that may be filled in the first photodetector (LPD) increases, the length of the first period (T1′) can be longer than the length of the first period (T1) described in FIG. 7. That is, since a sufficient length of the first period (T1′) is secured even in a high-illumination environment, auto-focusing may be possible.

The description of the second to fourth periods (T2′, T3′, and T4′) is omitted as it has been described above in FIGS. 7 to 10.

The image sensing device according to the embodiments of the present disclosure may be described as follows.

In one aspect, an image sensing device is provided to comprise: a first photodetector disposed in a first pixel area; a second photodetector disposed in a second pixel area disposed on one side of the first pixel area, each of the first photodetector and the second photodetector configured to produce electrical signals in response to incident light; a charge flooding barrier disposed in a non-pixel area located between the first pixel area and the second pixel area, the non-pixel area disposed without including any photodetector for detecting the incident light; and a charge flooding barrier control node overlapping the charge flooding barrier and configured to control a potential of the charge flooding barrier.

In some implementations, the potential of the charge flooding barrier is variable based on a voltage applied to the charge flooding barrier control node.

In some implementations, the potential of the charge flooding barrier is smaller than a potential of the first photodetector and a potential of the second photodetector.

In some implementations, the image sensing device further comprises: a non-charge flooding barrier disposed in the non-pixel area and disposed above or below the charge flooding barrier, wherein a potential of the non-charge flooding barrier is smaller than the potential of the charge flooding barrier.

In some implementations, the image sensing device further comprises: a control line connected to the charge flooding barrier control node, and a negative bias voltage is applied to the control line.

In some implementations, the image sensing device further comprises: a second layer between the charge flooding barrier control node and the charge flooding barrier in the non-pixel area, wherein the second layer is in direct contact with the charge flooding barrier control node.

In some implementations, the second layer has an electrical conductivity.

In some implementations, the second layer comprises a polysilicon.

In some implementations, the image sensing device further comprises: a third layer between the charge flooding barrier control node and the second layer in the non-pixel area, wherein the third layer comprises an insulating material.

In some implementations, the third layer surrounds the charge flooding barrier of the non-pixel area and the non-charge flooding barrier disposed above or below the charge flooding barrier.

In some implementations, the second layer surrounds the third layer.

In some implementations, the image sensing device further comprises: a first layer between the second layer and a separator of the non-pixel area in the non-pixel area, wherein the first layer comprises an insulating material.

In some implementations, the first layer is in direct contact with the second layer and the separator.

In another aspect, an image sensing device comprising: a first photodetector and a second photodetector that are configured to generate photocharges corresponding to an intensity of incident light; a first transfer transistor connected between the first photodetector and a floating diffusion area and configured to transfer photocharges accumulated in the first photodetector to the floating diffusion area; a second transfer transistor connected to the second photodetector and the floating diffusion area and configured to transfer photocharges accumulated in the second photodetector to the floating diffusion area; and a charge flooding barrier control node disposed between the first transfer transistor and the floating diffusion area and between the second transfer transistor and the floating diffusion area, the charge flooding barrier control node configured to control a potential of a charge flooding barrier disposed between the first photodetector and the second photodetector.

In some implementations, the potential of the charge flooding barrier is variable.

In some implementations, the potential of the charge flooding barrier is lower than a potential of the first photodetector and equal to or higher than a potential of the first transfer transistor.

In some implementations, a negative bias voltage is applied to the charge flooding barrier control node.

In some implementations, the image sensing device further comprises: a reset transistor connected to the floating diffusion area.

In some implementations, the image sensing device further comprises: a driver transistor comprising a gate electrode connected to the floating diffusion area, a first electrode to which a power supply voltage is applied, and a second electrode.

In some implementations, the image sensing device further comprises: a selection transistor comprising a third electrode connected to the second electrode of the driver transistor, a gate electrode, and a fourth electrode connected to an output line.

While various embodiments have been described with reference to the exemplified drawings, variations and improvements of the disclosed embodiments and other embodiments may be made based on what is described or illustrated in this document

1. An image sensing device, comprising:
a first photodetector disposed in a first pixel area;
a second photodetector disposed in a second pixel area disposed on one side of the first pixel area, each of the first photodetector and the second photodetector configured to produce electrical signals in response to incident light;
a charge flooding barrier disposed in a non-pixel area located between the first pixel area and the second pixel area, the non-pixel area disposed without including any photodetector for detecting the incident light; and
a charge flooding barrier control node overlapping the charge flooding barrier and configured to control a potential of the charge flooding barrier.

2. The image sensing device of claim 1, wherein the potential of the charge flooding barrier is variable based on a voltage applied to the charge flooding barrier control node.

3. The image sensing device of claim 1, wherein the potential of the charge flooding barrier is smaller than a potential of the first photodetector and a potential of the second photodetector.

4. The image sensing device of claim 1, further comprising:
a non-charge flooding barrier disposed in the non-pixel area and disposed above or below the charge flooding barrier,
wherein a potential of the non-charge flooding barrier is smaller than the potential of the charge flooding barrier.

5. The image sensing device of claim 1, further comprising:
a control line connected to the charge flooding barrier control node, and a negative bias voltage is applied to the control line.

6. The image sensing device of claim 1, further comprising:
a second layer between the charge flooding barrier control node and the charge flooding barrier in the non-pixel area,
wherein the second layer is in direct contact with the charge flooding barrier control node.

7. The image sensing device of claim 6, wherein the second layer has an electrical conductivity.

8. The image sensing device of claim 7, wherein the second layer comprises a polysilicon.

9. The image sensing device of claim 6, further comprising:
a third layer between the charge flooding barrier control node and the second layer in the non-pixel area,
wherein the third layer comprises an insulating material.

10. The image sensing device of claim 9, wherein the third layer surrounds the charge flooding barrier of the non-pixel area and a non-charge flooding barrier disposed above or below the charge flooding barrier.

11. The image sensing device of claim 9, wherein the second layer surrounds the third layer.

12. The image sensing device of claim 6, further comprising:
a first layer between the second layer and a separator of the non-pixel area in the non-pixel area,
wherein the first layer comprises an insulating material.

13. The image sensing device of claim 12, wherein the first layer is in direct contact with the second layer and the separator.

14. An image sensing device comprising:
a first photodetector and a second photodetector that are configured to generate photocharges corresponding to an intensity of incident light;
a first transfer transistor connected between the first photodetector and a floating diffusion area and configured to transfer photocharges accumulated in the first photodetector to the floating diffusion area;
a second transfer transistor connected to the second photodetector and the floating diffusion area and configured to transfer photocharges accumulated in the second photodetector to the floating diffusion area; and
a charge flooding barrier control node disposed between the first transfer transistor and the floating diffusion area and between the second transfer transistor and the floating diffusion area, the charge flooding barrier control node configured to control a potential of a charge flooding barrier disposed between the first photodetector and the second photodetector.

15. The image sensing device of claim 14, wherein the potential of the charge flooding barrier is variable.

16. The image sensing device of claim 15, wherein the potential of the charge flooding barrier is lower than a potential of the first photodetector and equal to or higher than a potential of the first transfer transistor.

17. The image sensing device of claim 14, wherein a negative bias voltage is applied to the charge flooding barrier control node.

18. The image sensing device of claim 14, further comprising:
a reset transistor connected to the floating diffusion area.

19. The image sensing device of claim 14, further comprising:
a driver transistor comprising a gate electrode connected to the floating diffusion area, a first electrode to which a power supply voltage is applied, and a second electrode.

20. The image sensing device of claim 19, further comprising:
a selection transistor comprising a third electrode connected to the second electrode of the driver transistor, a gate electrode, and a fourth electrode connected to an output line.
